(19) United States
(12) Patent Application Publication
(10) Pub. No.: US 2026/0005672 A1
(43) Pub. Date: Jan. 1, 2026

(54) BANDPASS FILTER CIRCUIT

(71) Applicant: STMICROELECTRONICS INTERNATIONAL N.V., Geneva (CH)

(72) Inventor: Benoit BONNET, Tours (FR)

(21) Appl. No.: 19/236,194

(22) Filed: Jun. 12, 2025

(30) Foreign Application Priority Data
Jun. 26, 2024 (FR) FR2406847

(51) Int. Cl. H03H 9/54; H03H 9/56

(52) U.S. Cl. CPC H03H 9/542; H03H 9/566

(57) ABSTRACT

The present disclosure provides a bandpass filter circuit. An example band pass filter circuit comprises, in series, a first high-pass filter, a bandpass filter, and a second high-pass filter. The bandpass filter comprises: first and second acoustic resonators serially disposed between first and second nodes; two first coils disposed in series with each other, and disposed in parallel to the first acoustic resonator; two second coils disposed in series with each other, and disposed in parallel to the second acoustic resonator; a third acoustic resonator disposed between a third mid-node between the first coils and a fourth node; and a fourth acoustic resonator disposed between a fifth mid-node between the second coils and the fourth node.

### CROSS REFERENCE TO RELATED APPLICATION(S)

This application claims the priority benefit of French Patent Application Number FR2406847, filed on Jun. 26, 2024, entitled “CIRCUIT DE FILTRAGE PASSE-BANDE” which is hereby incorporated by reference to the maximum extent allowable by law.

### TECHNICAL FIELD

The present description relates generally to processing and transmitting periodic signals such as radiofrequency signals. More particularly, the present description relates to performing an operation of filtering a radiofrequency signal.

### BACKGROUND

Periodic signals, such as radiofrequency signals, are commonly used in transmitting information. Their processing is critical for correctly transmitting data.

Using filters having different types is a part of conventional processes applied to periodic signals.

It would be desirable to be able to improve at least in part some features of the circuits for filtering the periodic signals.

### BRIEF SUMMARY

There is a need for more efficient circuits for filtering periodic signals.

There is a need for more efficient circuits for filtering radiofrequency signals.

There is a need for more efficient bandpass circuits for filtering radiofrequency signals.

There is a need for bandpass circuits for filtering radiofrequency signals allowing signals with a frequency comprised in a wider frequency band to be filtered.

There is a need for a filtering method having these same advantages.

There is a need for a transmission chain using such a filter circuit.

There is a need for a signal transmission method having these same advantages.

One embodiment overcomes some or part of the drawbacks of known filter circuits.

One embodiment overcomes some or part of the drawbacks of known signal filtering methods.

One embodiment overcomes some or part of the drawbacks of known transmission chains.

One embodiment overcomes some or part of the drawbacks of known transmission methods.

One embodiment provides a bandpass filter circuit comprising, in series, a first high-pass filter, a bandpass filter, and a second high-pass filter, wherein the bandpass filter comprises:
a first acoustic resonator and a second acoustic resonator serially disposed between a first node and a second node;
at least two first coils disposed in series with each other, and disposed in parallel to the first acoustic resonator;
at least two second coils disposed in series with each other, and disposed in parallel to the second acoustic resonator;
at least one third acoustic resonator disposed between a third mid-node between the first coils and a fourth reference node; and
at least one fourth acoustic resonator disposed between a fifth mid-node between the second coils and the fourth reference node.

Another embodiment provides a method for filtering a radiofrequency signal using a bandpass filter circuit comprising, in series, a first high-pass filter, a bandpass filter, and a second high-pass filter, wherein the bandpass filter comprises:
a first acoustic resonator and a second acoustic resonator serially disposed between a first node and a second node;
at least two first coils disposed in series with each other, and disposed in parallel to the first acoustic resonator;
at least two second coils disposed in series with each other, and disposed in parallel to the second acoustic resonator;
at least one third acoustic resonator disposed between a third mid-node between the first coils and a fourth reference node; and
at least one fourth acoustic resonator disposed between a fifth mid-node between the second coils and the fourth reference node.

According to an embodiment, the first and second acoustic resonators are identical to each other,

wherein the first coils are identical to the second coils, and the third and fourth acoustic resonators are identical to each other.

According to an embodiment, the first acoustic resonator can comprise at least two fifth acoustic resonators serially disposed.

According to an embodiment, the second acoustic resonator can comprise at least two sixth acoustic resonators serially disposed.

According to an embodiment, the first high-pass filter comprises:
two first capacitors disposed in series between a sixth node and the first node; and
a second capacitor and a third coil disposed in series between a seventh mid-node between the first capacitors and the fourth reference node.

According to an embodiment, the second high-pass filter comprises:
two third capacitors disposed in series between the second node and an eighth node; and
a fourth capacitor and a fourth coil disposed in series between a ninth mid-node between the second capacitors and the fourth reference node.

According to an embodiment, the first and second high-pass filters are symmetrical with respect to the bandpass filter.

According to an embodiment, the filter circuit further comprises a fifth coil disposed in series between the sixth node and the fourth reference node.

According to an embodiment, the filter circuit further comprises a sixth coil disposed in series between the seventh node and the fourth reference node.

Another embodiment provides a transmission chain comprising a filter circuit previously described.

Another embodiment provides a method for transmitting a signal using the filtering method previously described.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates a diagram showing a first embodiment of a bandpass filter circuit;

FIG. 2 comprises graphs showing the operation of the embodiment shown in FIG. 1;

FIG. 3 comprises a graph showing the operation of the embodiment shown in FIG. 1;

FIG. 4 illustrates a diagram showing a second embodiment of a bandpass filter circuit;

FIG. 5 comprises graphs showing the operation of the embodiment shown in FIG. 4;

FIG. 6 comprises a graph showing the operation of the embodiment shown in FIG. 4; and

FIG. 7 illustrates a top view of a practical implementation of the embodiments shown in FIGS. 1 and 4.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of”signify within 10%, and preferably within 5%.

The embodiments described hereinafter relates to the filtering of periodic signals, and more particularly the filtering of radiofrequency signals, i.e. signals the frequencies of which range from 3 kHz to 300 GHz. More precisely, the embodiments described hereinafter are passband filter circuits the isolation and rejection characteristics of which were improved so as to use them in the field of communications using wireless communication protocol sets, such as Wi-Fi communication protocols. To this end, these filter circuits are designed to let through signals with frequencies ranging from 6 GHz to 7.2 GHz, more particularly ranging from 6.105 GHz and 7.125 GHz, and to reject signals with frequencies around 5 GHz. These embodiments are described in detail in relation to FIGS. 1 to 7. These embodiments are particularly suitable for use in transmission chains of information and/or data.

In addition, the embodiments described hereinafter are particularly suitable for use in any type of industrial markets where filtering periodic signals is useful. More particularly, such a passband filter circuit may be intended to:
automotive industry, such as in the field of automotive electrification and the automotive telematic, or in the field of Advanced Driver Assistance Systems (ADAS);
the industrial industry, for example in the field of green energy, in the field of electrification of infrastructure, of the internet of things (IoT), and of smart homes, wherein power and energy consumption and the exchange of data are key element;
the personal electronics industry, for example in the field of mobile phone and of the internet of things (IoT), and in the field of high speed-interface; and
the communications equipment, computers and peripherals industry, for example in the field of infrastructure and data centers, and in the field of satellites in low earth orbit (LEO).

FIG. 1 illustrates an electric diagram of a first embodiment of a bandpass filter circuit 100.

The circuit 100 comprises an input node IN100 and an output node OUT100. The input node IN100 is suitable to receive periodic signals intended to be filtered. The output node OUT100 is suitable to provide filtered periodic signals. The circuit 100 is further referenced to a reference node GND1100 receiving a reference potential, such as ground.

Optionally, the circuit 100 further comprises a first coil L101 for electrostatic discharge protection. A first terminal of the coil L101 is coupled, preferably connected, to the input node IN100, and a second terminal of the coil L101 is coupled, preferably connected, to the reference node GND100.

Optionally, the circuit 100 further comprises a second coil L102 for electrostatic discharge protection. A first terminal of the coil L102 is coupled, preferably connected, to the output node OUT100, and a second terminal of the coil L102 is coupled, preferably connected, to the reference node GND100.

According to one embodiment, the circuit 100 further comprises a first high-pass filter HPF110 comprising an input node coupled, preferably connected, to the input node IN100, and an output node N102. According to one example, the filter HPF110 comprises three capacitors CHPF111, CHPF112, and CHPF113, and a coil LHPF111.

According to one example, the capacitors CHPF111 and CHPF112 are disposed in series between nodes IN100 and N102. More particularly, a first terminal of the capacitor CHPF111 is coupled, preferably connected, to node IN100, and a second terminal of the capacitor CHPF111 is coupled, preferably connected, to a node N101. A first terminal of the capacitor HPF112 is coupled, preferably connected, to node N101, and a second terminal of the capacitor HPF112 is coupled, preferably connected, to node N102.

According to one example, the capacitor CHPF113 and the coil LHPF111 are disposed in series between nodes N101 and GND100. More particularly, a first terminal of the capacitor CHPF113 is coupled, preferably connected, to node N101, and a second terminal of the capacitor CHPF113 is coupled, preferably connected, to a first terminal of the coil LHPF111. A second terminal of the coil LHPF111 is coupled, preferably connected, to node GND100.

Filter HPF110 described here is a high-pass filter of the 1^{st} order. Alternatively, filter HPF110 could be a high-pass filter of higher order.

According to one embodiment, the circuit further comprises a passband filter BPF100 comprising an input node coupled, preferably connected, to the output node N102 of the high-pass filter HPF110, and an output node N103. According to one example, the filter BPF110 comprises four acoustic resonators AWR101, AWR102, AWR103, and AWR104, and four coils LBPF101, LBPF102, LBPF103, and LBPF104. Here is called acoustic resonator a mechanical and electronic component using, for example, a piezoelectric material resonating between two conductive plates, such as metal plates.

According to one embodiment, the resonators AWR101 and AWR102 are disposed in series between nodes N102 and N103. More particularly, a first terminal of the resonator AWR101 is coupled, preferably connected, to node N102, and a second terminal of the resonator AWR101 is coupled, preferably connected, to a node N104. A first terminal of the resonator AWR102 is coupled, preferably connected, to node N104, and a second terminal of the resonator AWR102 is coupled, preferably connected, to node N103.

According to an alternative embodiment, each resonator AWR101, AWR102 could be replaced with a serial assembly of at least two acoustic resonators. It could advantageously reduce the whole capacitance of the filter circuit 100. Furthermore, this can have the advantage of increasing the surface area of the acoustic resonators while retaining the value of the total capacitance of the circuit to facilitate manufacturing and have better power handling.

According to one embodiment, the coils LBPF101 and LBPF102 are disposed in series between the nodes N102 and N104. In other words, the coils LBPF101 and LBPF102 are disposed in series with each other, and in parallel to the acoustic resonator AWR101. More particularly, a first terminal of the coil LBPF101 is coupled, preferably connected, to node N102, and a second terminal of the coil LBPF101 is coupled, preferably connected, to a node N105. A first terminal of the coil LBPF102 is coupled, preferably connected, to node N105, and a second terminal of the coil LBPF102 is coupled, preferably connected, to node N104.

According to one embodiment, the coils LBPF103 and LBPF104 are disposed in series between the nodes N104 and N103. In other words, the coils LBPF103 and LBPF104 are disposed in series with each other, and in parallel to the acoustic resonator AWR102. More particularly, a first terminal of the coil LBPF103 is coupled, preferably connected, to node N104, and a second terminal of the coil LBPF103 is coupled, preferably connected, to a node N106. A first terminal of the coil LBPF104 is coupled, preferably connected, to node N106, and a second terminal of the coil LBPF104 is coupled, preferably connected, to node N103.

According to one embodiment, the resonator AWR103 couples node N105 to the reference node GND100. In other words, a first terminal of resonator AWR103 is coupled, preferably connected, to node N105 and a second terminal of resonator AWR103 is coupled, preferably connected, to node GND100.

According to one embodiment, the resonator AWR104 couples node N106 to the reference node GND100. In other words, a first terminal of resonator AWR104 is coupled, preferably connected, to node N106 and a second terminal of resonator AWR104 is coupled, preferably connected, to node GND100.

According to an alternative embodiment, each resonator AWR103, AWR104 could be replaced with a serial assembly of at least two acoustic resonators. It could advantageously reduce the whole capacitance of the filter circuit 100. Furthermore, this can have the advantage of increasing the surface area of the acoustic resonators while retaining the value of the total capacitance of the circuit to facilitate manufacturing and have better power handling.

According to one embodiment, the circuit further comprises a second high-pass filter HPF120 comprising an input node coupled, preferably connected, to the output node N103 of the bandpass BPF100, and an output node coupled, preferably connected, to the output node OUT100. According to one example, the filter HPF120 comprises three capacitors CHPF121, CHPF122, and CHPF123, and a coil LHPF121.

According to one example, the capacitors CHPF121 and CHPF122 are serially disposed between the nodes N103 and OUT100. More particularly, a first terminal of capacitor CHPF121 is coupled, preferably connected, to node N103, and a second terminal of capacitor CHPF121 is coupled, preferably connected, to a node N107. A first terminal of capacitor CHPF122 is coupled, preferably connected, to node N107, and a second terminal of capacitor CHPF122 is coupled, preferably connected, to node OUT100.

According to one example, the capacitor CHPF121 and coil LHPF121 are serially disposed between nodes N107 and GND100. More particularly, a first terminal of capacitor CHPF123 is coupled, preferably connected, to node N107, and a second terminal of capacitor CHPF123 is coupled, preferably connected, to a first terminal of coil LHPF121. A second terminal of coil LHPF121 is coupled, preferably connected, to node GND100.

The filter HPF120 described here is a high-pass filter of the first order. According to one alternative embodiment, the filter HPF120 could be a high-pass filter of higher order.

According to a practical example of the present disclosure, the components of the filter circuit 100 can have the following numerical values. It should be noted that other values can be imagined and their determination is within the reach of the person skilled in the art.

In the HPF110 high-pass filter:
the capacitor CHPF111 has a capacity of between 0.1 and 5 pF, for example of the order of 0.53 pF;
the capacitor CHPF112 has a capacity of between 0.1 and 5 pF, for example of the order of 0.61 pF;
the capacitor CHPF113 has a capacity of between 0.1 and 5 pF, for example of the order of 1.53 pF; and
the LHPF111 coil has an inductance of between 0.1 and 5 nH, for example of the order of 1.51 nH.

In the BPF100 bandpass filter:
the LHPF101 coil has an inductance of between 0.1 and 5 nH, for example of the order of 1.61 nH;
the LHPF102 coil has an inductance of between 0.1 and 5 nH, for example of the order of 1 nH;
the LHPF103 coil has an inductance of between 0.1 and 5 nH, for example of the order of 1.4 nH;
the LHPF104 coil has an inductance of between 0.1 and 5 nH, for example of the order of 0.93 nH;
the acoustic resonator AWR101 has a capacitance of between 0.1 and 5 pF, for example of the order of 0.524 pF, has a resonance frequency of between 5 and 10 GHz, for example of the order of 6.51 GHz, and has an antiresonance frequency of between 5 and 10 GHz, for example of the order of 7.02 GHz;
the AWR102 acoustic resonator has a capacitance of between 0.1 and 5 pF, for example of the order of 0.314 pF, has a resonance frequency of between 5 and 10 GHz, for example of the order of 6.46 GHz, and has an antiresonance frequency of between 5 and 10 GHz, for example of the order of 6.98 GHz;
the AWR103 acoustic resonator has a capacitance of between 0.1 and 5 pF, for example of the order of 0.206 pF, has a resonance frequency of between 5 and 10 GHz, for example of the order of 6.09 GHz, and has an antiresonance frequency of between 5 and 10 GHz, for example of the order of 6.57 GHz; and
the AWR104 acoustic resonator has a capacitance of between 0.1 and 5 pF, for example of the order of 0.200 pF, has a resonance frequency of between 5 and 10 GHz, for example of the order of 6.10 GHz, and has an antiresonance frequency of between 5 and 10 GHz, for example of the order of 6.57 GHz.

In the HPF120 high-pass filter:
the capacitor CHPF121 has a capacity of between 0.1 and 5 pF, for example of the order of 1.86 pF;
the CHPF122 capacitor has a capacity of between 0.1 and 5 pF, for example of the order of 1.75 pF;
the capacitor CHPF123 has a capacity of between 0.1 and 5 pF, for example of the order of 1 pF; and
the LHPF121 coil has an inductance of between 0.1 and 5 nH, for example of the order of 1.76 nH.

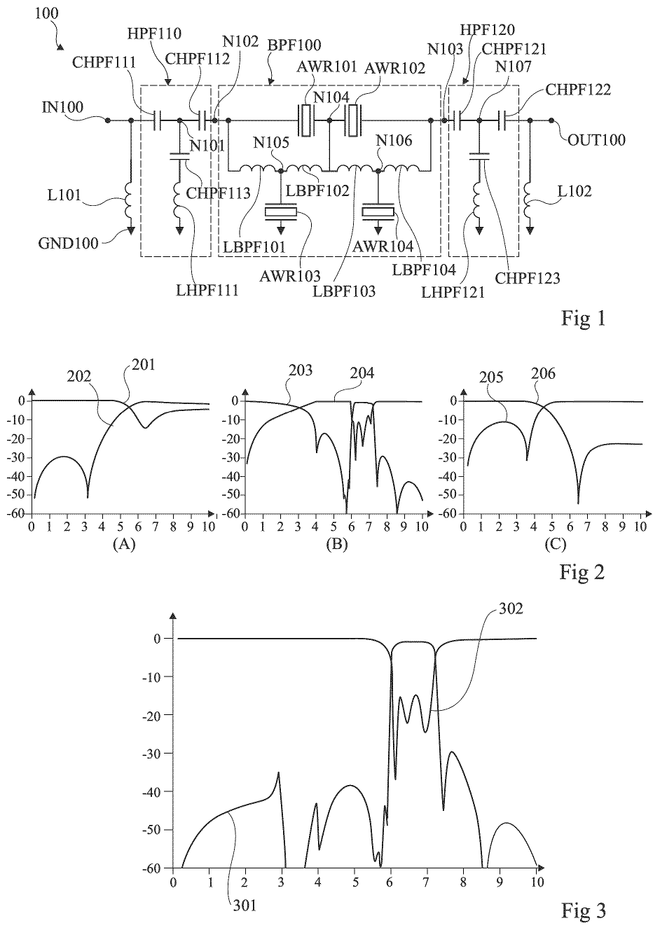

The operation of the passband filter circuit 100 is described in detail in relation to FIGS. 2 and 3.

A method for filtering a periodic signal, such as a radiofrequency signal, using a filter circuit of the type of the filter circuit 100 described here is also within the scope of the present disclosure.

In addition, the bandpass filter circuit 100 can be used within a chain for transmitting information and/or data. A method for transmitting information and/or data using such a transmission chain is within the scope of the present disclosure.

FIG. 2 comprises three graphs (A), (B), and (C) showing the operation of three filters included in the filter circuit 100 described in relation with FIG. 1.

More particularly, the graph (A) illustrates the operation of the high-pass filter HPF110. The graph (B) illustrates the operation of the passband filter BPF100. The graph (C) illustrates the operation of the high-pass filter HPF120.

Each of the graphs (A), (B), and (C) comprises two curves illustrating the performances in terms of matching and attenuation of the filter according to the frequency of the signal received by the filter. More particularly, a first curve represents the adaptation of the filter, that is to say the ratio of the reflected power and the incident power in decibels, also called Return Loss. A second curve represents the attenuation of the filter, that is to say the relative reduction in the power of a signal during transmission which can be expressed by the ratio between the power of the input signal and that of the output signal (ratio measured in decibels).

In particular, the graph (A) comprises a curve 201 illustrating the matching of the high-pass filter HPF110, and a curve 202 illustrating the attenuation of the high-pass filter HPF110. To perform this simulation, are considered an input signal applied at the node IN100 and an output signal provided by the node N102. Curves 201 and 202 show that the filter HPF110 rejects any signal having a frequency less than 5 GHz, and has a low insertion loss for the signals having a frequency higher than 5 GHz.

The graph (B) comprises a curve 203 illustrating the matching of the bandpass filter BPF100, and a curve 204 illustrating the matching of the bandpass filter BPF100. To perform this simulation, are considered an input signal applied at the node N102 and an output signal provided by the node N103. Curves 203 and 204 show that the filter BPF100 let through any signal having a frequency between around 6 GHz and 7.5 GHz, and has an attenuation for the signals having a frequency ranging from around 3 GHz to 6 GHz and higher than 7 GHz.

The graph (C) comprises a curve 205 illustrating the attenuation of the bandpass filter HPF120, and a curve 208 illustrating the matching of the high-pass filter HPF120. To perform this simulation, are considered an input signal applied at the node N103 and an output signal provided by the node OUT100. Curves 205 and 206 show that the filter HPF120 rejects any signal having a frequency less than around 4 GHz, and has a low insertion loss for the signals having a frequency higher than 4 GHz.

FIG. 3 is a graph illustrating the operation of the circuit 100 described in relation to FIG. 1.

More particularly, the graph shown in FIG. 3 illustrates the operation of the filter circuit 100, i.e. the combination of the filters HPF110, BPF100, and HPF120 the operation of which were described previously.

As graphs (A), (B), and (C), the graph shown in FIG. 3 thus comprises two curves illustrating the performances in terms of matching and attenuation of the filter according to the frequency of the signal received by the filter. More particularly, a first curve represents the adaptation of the filter, that is to say the ratio of the reflected power and the incident power in decibels, also called Return Loss. A second curve represents the attenuation of the filter, that is to say the relative reduction in the power of a signal during transmission which can be expressed by the ratio between the power of the input signal and that of the output signal (ratio measured in decibels).

The graph shown in FIG. 3 thus comprises a curve 301 illustrating the attenuation of the bandpass filter circuit 100, and a curve 302 illustrating the matching of the bandpass filter circuit 100. To perform this simulation, are considered an input signal applied at the node IN100 and an output signal provided by the node OUT100. Curves 301 and 302 show that the filter circuit 100 rejects any signal having a frequency less than 6 GHz, and higher than around 7.2 GHz.

One advantage of the filter circuit 100 shown in FIG. 1 is it allows an attenuation or a rejection less than −40 dB, around −49 dB, for a signal having a frequency around 5.895 GHz, to be obtained.

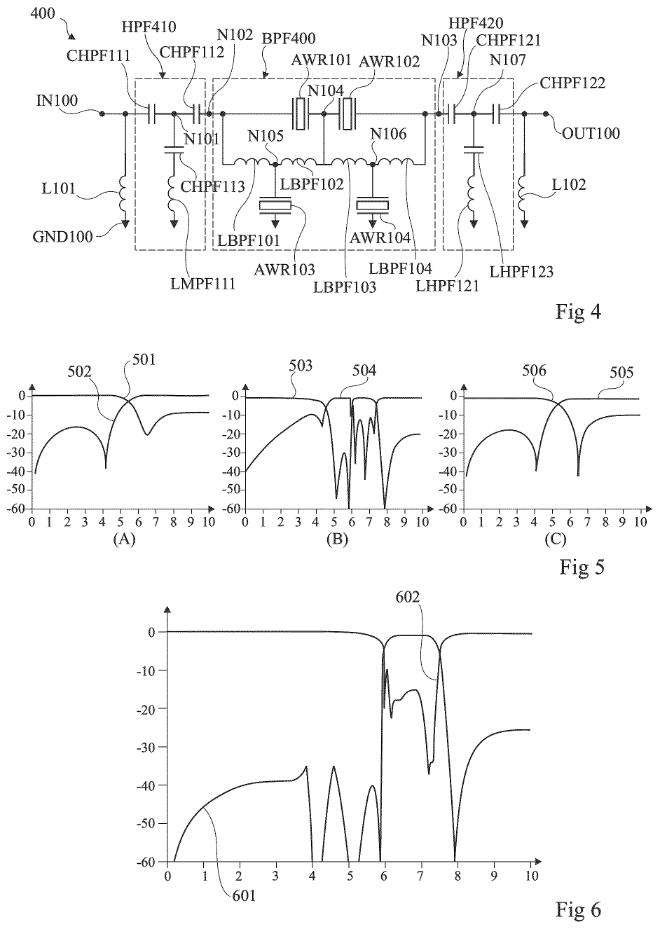

FIG. 4 illustrates an electric diagram of a first embodiment of a bandpass filter circuit 400.

The bandpass filter circuit 400 is similar to the bandpass filter circuit 100 described in relation to FIG. 1. The features in common with circuits 100 and 400 are not described again in detail here. Only the differences between the circuits 100 and 400 are highlighted.

The bandpass filter circuit 400 comprises the same components as the bandpass filter circuit 100, but further has a symmetry in the characteristics of these components. More particularly, the node N104 forms a symmetry axis of the circuit 400.

Particularly, are identical two by two the following components:
the capacitor CHPF111 of the filter HPF110, and the capacitor CHPF122 of the filter HPF120;
the capacitor CHPF112 of the filter HPF110, and the capacitor CHPF121 of the filter HPF120;
the capacitor CHPF113 of the filter HPF110, and the capacitor CHPF123 of the filter HPF120;
the coil LHPF111 of the filter HPF110, and the coil LHPF121 of the filter HPF120;
the resonators AWR101 and AWR102 of the filter BPF100;
the coils LBPF101 and LBPF104 of the filter BPF100;
the coils LBPF102 and LBPF103 of the filter BPF100; and
the resonators AWR103 and AWR104 of the filter BPF100.

According to a practical example of the present disclosure, the components of the filter circuit 400 can have the following numerical values. It should be noted that other values can be imagined and their determination is within the reach of the person skilled in the art.

In the HPF410 high-pass filter:
the capacitor CHPF111 has a capacity of between 0.1 and 5 pF, for example of the order of 0.86 pF;
the capacitor CHPF112 has a capacity of between 0.1 and 5 pF, for example of the order of 0.96 pF;
the capacitor CHPF113 has a capacity of between 0.1 and 5 pF, for example of the order of 0.84 pF; and
the LHPF111 coil has an inductance of between 0.1 and 5 nH, for example of the order of 1.57 nH.

In the BPF400 bandpass filter:
the LHPF101 coil has an inductance of between 0.1 and 5 nH, for example of the order of 0.74 nH;
the LHPF102 coil has an inductance of between 0.1 and 5 nH, for example of the order of 0.74 nH;
the LHPF103 coil has an inductance of between 0.1 and 5 nH, for example of the order of 0.51 nH;
the LHPF104 coil has an inductance of between 0.1 and 5 nH, for example of the order of 0.51 nH;
the acoustic resonator AWR101 has a capacitance of between 0.1 and 5 pF, for example of the order of 0.587 pF, has a resonance frequency of between 5 and 10 GHz, for example of the order of 6.51 GHz, and has an antiresonance frequency of between 5 and 10 GHz, for example of the order of 7.03 GHz;
the AWR102 acoustic resonator has a capacitance of between 0.1 and 5 pF, for example of the order of 0.264 pF, has a resonance frequency of between 5 and 10 GHz, for example of the order of 6.01 GHz, and has an antiresonance frequency of between 5 and 10 GHz, for example of the order of 6.51 GHz;
the AWR103 acoustic resonator has a capacitance of between 0.1 and 5 pF, for example of the order of 0.206 pF, has a resonance frequency of between 5 and 10 GHz, for example of the order of 6.09 GHz, and has an antiresonance frequency of between 5 and 10 GHz, for example of the order of 6.57 GHz; and
the AWR104 acoustic resonator has a capacitance of between 0.1 and 5 pF, for example of the order of 0.200 pF, has a resonance frequency of between 5 and 10 GHz, for example of the order of 6.10 GHz, and has an antiresonance frequency of between 5 and 10 GHz, for example of the order of 6.57 GHz.

In the HPF420 high-pass filter:
the capacitor CHPF121 has a capacity of between 0.1 and 5 pF, for example of the order of 0.86 pF;
the CHPF122 capacitor has a capacity of between 0.1 and 5 pF, for example of the order of 0.93 pF;
the capacitor CHPF123 has a capacity of between 0.1 and 5 pF, for example of the order of 0.84 pF; and
the LHPF121 coil has an inductance of between 0.1 and 5 nH, for example of the order of 1.57 nH.

FIG. 5 comprises three graphs (A), (B), and (C) illustrating the operation of the three filters comprised in the filter circuit 400 described in relation to FIG. 4.

More particularly, the graph (A) illustrates the operation of the high-pass filter HPF400. The graph (B) illustrates the operation of the bandpass filter BPF400. The graph (C) illustrates the operation of the high-pass filter HPF420.

As described in relation to FIG. 2, each of the graphs (A), (B), and (C) comprises two curves illustrating the performances in terms of matching and attenuation of the filter according to the frequency of the signal received by the filter. More particularly, a first curve represents the adaptation of the filter, that is to say the ratio of the reflected power and the incident power in decibels, also called Return Loss. A second curve represents the attenuation of the filter, that is to say the relative reduction in the power of a signal during transmission which can be expressed by the ratio between the power of the input signal and that of the output signal (ratio measured in decibels).

Particularly, the graph (A) comprises a curve 501 illustrating the matching of the high-pass filter HPF410, and a curve 502 illustrating the attenuation of the high-pass filter HPF410. To perform this simulation, are considered an input signal applied at the node IN100 and an output signal provided by the node N102. Curves 501 and 502 show that the filter HPF410 rejects any signal having a frequency less than 5 GHz, and has a low insertion loss for the signals having a frequency higher than 5 GHz.

The graph (B) comprises a curve 503 illustrating the matching of the bandpass filter BPF400, and a curve 504 illustrating the matching of the bandpass filter BPF400. To perform this simulation, are considered an input signal applied at the node N102 and an output signal provided by the node N103. Curves 503 and 504 show that the filter HPF400 let through any signal having a frequency less than 4.5 GHz, and ranging from around 6 GHz and 7.5 GHz, and has an attenuation or rejection for the signals having a frequency ranging from around 4.5 GHz and 6 GHz and higher than 8 GHz.

The graph (C) comprises a curve 505 illustrating the attenuation of the high-pass filter HPF420, and a curve 506 illustrating the matching of the high-pass filter HPF420. To perform this simulation, are considered an input signal applied at the node N103 and an output signal provided by the node OUT100. Curves 505 and 506 show that the filter HPF420 rejects any signal having a frequency less than around 5 GHz, and has a low insertion loss for the signals having a frequency higher than 5 GHz.

FIG. 6 is a graph illustrating the operation of the circuit 400 described in relation to FIG. 4.

More particularly, the graph shown in FIG. 6 illustrates the operation of the filter circuit 400, i.e. the combination of the filters HPF410, BPF400, and HPF420 the operation of which were described previously.

Like graphs (A), (B), and (C), the graph shown in FIG. 5 thus comprises two curves illustrating the performances in terms of matching and attenuation of the filter according to the frequency of the signal received by the filter. More particularly, a first curve represents the adaptation of the filter, that is to say the ratio of the reflected power and the incident power in decibels, also called Return Loss. A second curve represents the attenuation of the filter, that is to say the relative reduction in the power of a signal during transmission which can be expressed by the ratio between the power of the input signal and that of the output signal (ratio measured in decibels).

The graph shown in FIG. 6 thus comprises a curve 601 illustrating the attenuation of the bandpass filter circuit 400, and a curve 602 illustrating the matching of the bandpass filter circuit 400. To perform this simulation, are considered an input signal applied at the node IN100 and an output signal provided by the node OUT100. Curves 601 and 602 show that the filter circuit 400 rejects any signal having a frequency less than 6 GHz, and higher than around 8 GHz.

One advantage of the filter circuit 100 shown in FIG. 1 is it allows a rejection gain less than −40 dB, around −38 dB, for a signal having a frequency around 5.895 GHz.

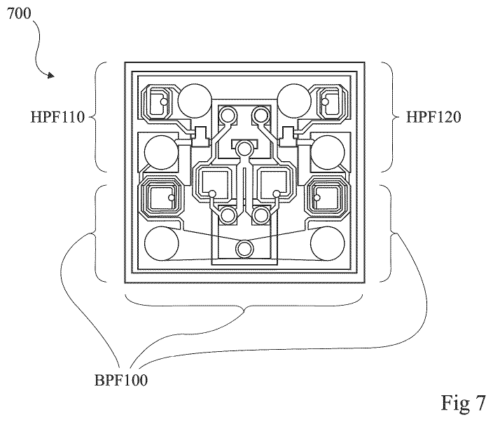

FIG. 7 is a top view illustrating a practical embodiment of a circuit 700 of the type of the bandpass filter circuits 100 and 400 described in relation to FIGS. 1 and 4.

FIG. 7 illustrates the location of different components of the bandpass filter circuits 100 and 400, and more particularly the location of the high-pass filter HPF110, bandpass filter BP100, and high-pass filter HPF120.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A bandpass filter circuit comprising, in series, a first high-pass filter, a bandpass filter, and a second high-pass filter, wherein the bandpass filter comprises:
a first acoustic resonator and a second acoustic resonator serially disposed between a first node and a second node;
at least two first coils disposed in series with each other, and disposed in parallel to the first acoustic resonator;
at least two second coils disposed in series with each other, and disposed in parallel to the second acoustic resonator;
at least one third acoustic resonator disposed between a third mid-node between the first coils and a fourth reference node; and
at least one fourth acoustic resonator disposed between a fifth mid-node between the second coils and the fourth reference node.

2. The bandpass filter circuit of claim 1, wherein the first and second acoustic resonators are identical to each other, wherein the first coils are identical to the second coils, and the third acoustic resonator and the fourth acoustic resonator are identical to each other.

3. The bandpass filter circuit of claim 1, wherein the first acoustic resonator can comprise at least two fifth acoustic resonators serially disposed.

4. The bandpass filter circuit of claim 1, wherein the second acoustic resonator can comprise at least two sixth acoustic resonators serially disposed.

5. The bandpass filter circuit of claim 1, wherein the first high-pass filter comprises:
two first capacitors disposed in series between a sixth node and the first node; and
a second capacitor and a third coil disposed in series between a seventh mid-node between the first capacitors and the fourth reference node.

6. The bandpass filter circuit of claim 1, wherein the second high-pass filter comprises:
two third capacitors disposed in series between the second node and an eighth node; and
a fourth capacitor and a fourth coil disposed in series between a ninth mid-node between the second capacitors and the fourth reference node.

7. The bandpass filter circuit of claim 1, wherein the first and second high-pass filters are symmetrical with respect to the bandpass filter.

8. The bandpass filter circuit of claim 5, wherein the filter circuit further comprises a fifth coil disposed in series between the sixth node and the fourth reference node.

9. The bandpass filter circuit of claim 5, wherein the filter circuit further comprises a sixth coil disposed in series between the seventh node and the fourth reference node.

10. A transmission chain comprising the filter circuit of claim 1.

11. A method for filtering a radiofrequency signal using a bandpass filter circuit comprising, in series, a first high-pass filter, a bandpass filter, and a second high-pass filter, wherein the bandpass filter comprises:
a first acoustic resonator and a second acoustic resonator serially disposed between a first node and a second node;
at least two first coils disposed in series with each other, and disposed in parallel to the first acoustic resonator;
at least two second coils disposed in series with each other, and disposed in parallel to the second acoustic resonator;
at least one third acoustic resonator disposed between a third mid-node between the first coils and a fourth reference node; and
at least one fourth acoustic resonator disposed between a fifth mid-node between the second coils and the fourth reference node.

12. The method of claim 11, wherein the first and second acoustic resonators are identical to each other, and wherein the first coils are identical to the second coils, and the third acoustic resonator and the fourth acoustic resonator are identical to each other.

13. The method of claim 11, wherein the first acoustic resonator can comprise at least two fifth acoustic resonators serially disposed.

14. The method of claim 11, wherein the second acoustic resonator can comprise at least two sixth acoustic resonators serially disposed.

15. The method of claim 11, wherein the first high-pass filter comprises:
two first capacitors disposed in series between a sixth node and the first node; and
a second capacitor and a third coil disposed in series between a seventh mid-node between the first capacitors and the fourth reference node.

16. The method of claim 11, wherein the second high-pass filter comprises:
two third capacitors disposed in series between the second node and an eighth node; and
a fourth capacitor and a fourth coil disposed in series between a ninth mid-node between the second capacitors and the fourth reference node.

17. The method of claim 11, wherein the first and second high-pass filters are symmetrical with respect to the bandpass filter.

18. The method of claim 15, wherein the filter circuit further comprises a fifth coil disposed in series between the sixth node and the fourth reference node.

19. The method of claim 15, wherein the filter circuit further comprises a sixth coil disposed in series between the seventh node and the fourth reference node.

20. A method for transmitting a signal using the method of claim 11.
